(19) United States
(12) Patent Application Publication
(10) Pub. No.: US 2006/0158110 A1
(43) Pub. Date: Jul. 20, 2006

(54) Organic light emitting diode display

(76) Inventors: Eun-Ah Kim, Suwon-si (KR); Jeong-No Lee, Suwon-si (KR)

Correspondence Address: CHRISTIE, PARKER & HALE, LLP, PO BOX 7068, PASADENA, CA, 91109-7068, US

(21) Appl. No.: 11/286,149

(22) Filed: Nov. 22, 2005

(30) Foreign Application Priority Data
Nov. 23, 2004 (KR) 10-2004-0096582

(51) Int. Cl. H05B 33/04; H01L 51/50

(52) U.S. Cl. 313/512; 313/506; 313/509

(57) ABSTRACT

Provided is an OLED display in which one surface is used as a display and the other surface is used as a mirror by forming a reflective layer to a predetermined thickness on a non-emission surface. The OLED display includes at least one OLED display element that includes a pixel electrode, an organic layer having at least an emission layer, an opposite electrode and a thin-film transistor. A top-emitting OLED display includes a reflective pixel electrode and a transparent opposite electrode. A bottom-emitting OLED display includes a transparent pixel electrode and a reflective opposite electrode. The reflective layer may be a metal layer having a reflectivity of approximately 70% or more, and may be formed of at least one material selected from the group consisting of Cr-based, Al-based, Ag-based, Sn-based, Mo-based, Fe-based, Pt-based, and Hg-based metals. The reflective layer may have a thickness of about 100 Å or more.

### CROSS-REFERENCE TO RELATED APPLICATION

This application claims priority to and the benefit of Korean Patent Application No. 10-2004-96582, filed Nov. 23, 2004 in the Korean Intellectual Property Office, the disclosure of which is incorporated herein by reference in its entirety.

### FIELD OF THE INVENTION

The present invention relates generally to an organic light emitting diode (OLED) display in which a reflective layer that may function as a mirror is disposed on a surface of the first substrate or the second substrate of the OLED display.

### BACKGROUND

In general, an OLED emits light by exciting fluorescent organic compounds. As used herein, the term “OLED display element” means an assembly of a thin-film transistor, a pixel electrode functioning as an anode, a portion of an opposite electrode disposed over the organic layer of one or more OLED display elements and functioning as a cathode, and an organic layer. As used herein, the term “OLED display element array” means one or more OLED display elements positioned over an area. As used herein, the term “OLED display” means an assembly of an OLED display element array, one or more substrates and at least one reflective layer. The OLED display can be classified into a passive matrix OLED (PMOLED) display or an active matrix OLED (AMOLED) display according to a driving method of N×M pixels, which are arranged in a matrix shape. In comparison with the PMOLED, the AMOLED is suitable for large-area displays due to its low power consumption and high resolution.

The OLED display can also be classified into either a top-emitting OLED display, a bottom-emitting OLED display or a double-side emitting OLED display based on the direction in which light is emitted to the substrates in the OLED display. Unlike the bottom-emitting OLED display, the top-emitting OLED display is a display in which light is emitted in an opposite direction to a substrate on which unit pixels are arranged and has an advantage of a high aperture ratio.

With the size reduction and low power consumption of displays, OLED displays including both a top-emitting main display window and a bottom-emitting auxiliary display window are increasing in demand. Such OLED displays are mostly used for mobile phones, which have an auxiliary display window outside the mobile phone and a main display window inside the mobile phone. In particular, the auxiliary display window consumes lower power than the main display window, and correspondingly, a mobile phone can remain turned on during use of call waiting. Further, a user can check reception status, remaining battery capacity, and the time at any time.

### SUMMARY

Exemplary embodiments provide an OLED display in which a reflective layer is disposed on a surface of the first substrate or the second substrate of the OLED display.

In an exemplary embodiment of the present invention, an OLED display includes: a first substrate having a first surface on which at least one OLED display element is disposed. The OLED display element includes a pixel electrode, an organic layer having at least an emission layer (EML), an opposite electrode and a thin-film transistor. A second substrate encapsulates the OLED display element and a reflective layer is disposed on a surface of the first substrate or the second substrate.

In another exemplary embodiment of the present invention, an OLED display includes: a first substrate having a first surface on which at least one OLED display element is disposed. The OLED display element includes a pixel electrode, an organic layer having at least an EML, an opposite electrode and a thin-film transistor. The first substrate has a second surface on which a reflective layer is disposed. A second substrate encapsulates the OLED display element.

In yet another exemplary embodiment of the present invention, an OLED display includes: a first substrate having a first surface on which at least one OLED display element is disposed. The OLED display element includes a pixel electrode, an organic layer having at least an EML, an opposite electrode and a thin-film transistor. A second substrate encapsulates the at least one OLED display element and has a surface on which a reflective layer is disposed.

### BRIEF DESCRIPTION OF THE DRAWINGS

FIG. 1 is a schematic cross-sectional view of a top-emitting OLED display according to an exemplary embodiment of the present invention;

FIG. 2A is a schematic cross-sectional view of a bottom-emitting OLED display having a reflective layer disposed on the surface of the second substrate according to another exemplary embodiment of the present invention;

FIG. 2B is a schematic cross-sectional view of a bottom-emitting OLED display with a reflective layer disposed on the second surface of the second substrate; and

FIG. 3 is a schematic perspective view of a mobile phone using an OLED display fabricated according to an embodiment of the present invention.

### DETAILED DESCRIPTION

Exemplary embodiments of the present invention will be described with reference to the accompanying drawings. In the drawings, when one element is connected to another element, the element may be directly connected to another element and also indirectly connected to a second element via a third element. Irrelative elements are omitted for clarity.

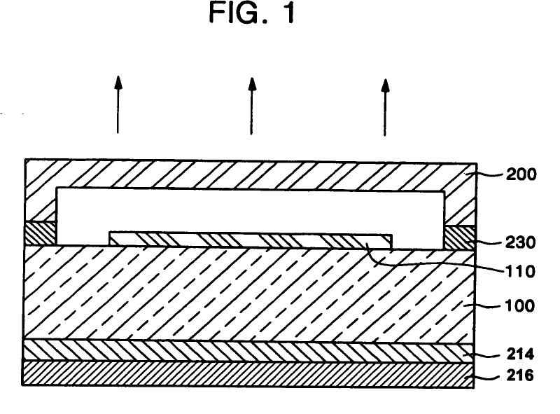

Referring to FIG. 1, an OLED display element array 110 is disposed on a first surface of a first substrate 100, and a reflective layer 214 is disposed on a second surface of the first substrate 100. The OLED display element array 110 may be encapsulated by a second substrate 200 corresponding to the first substrate 100 and adhered to the first substrate 100 by an adhesive 230. The OLED display element array 110 may be made up of one or more OLED display elements. The OLED display element includes a pixel electrode, an organic layer having at least an emission layer (EML), and an opposite electrode. The OLED display element also includes a thin-film transistor. The pixel electrode is a reflective electrode, while the opposite electrode is a transparent electrode. The reflective layer 214 of the OLED display may be formed of a material having a reflectivity of approximately 70% or more. The reflective layer may be formed of at least one material selected from the group including Cr-based, Al-based, Ag-based, Sn-based, Mo-based, Fe-based, Pt-based, and Hg-based metals, and may be formed to a thickness of about 100 Å or more. In this embodiment, since the reflective layer 214 is exposed, an optional passivation layer 216 may be formed on the exposed surface of the reflective layer 214 to protect the reflective layer 214. The arrows above the top-emitting OLED display illustrate the direction of OLED emission (and corresponding OLED display) out of the OLED display to the device owner.

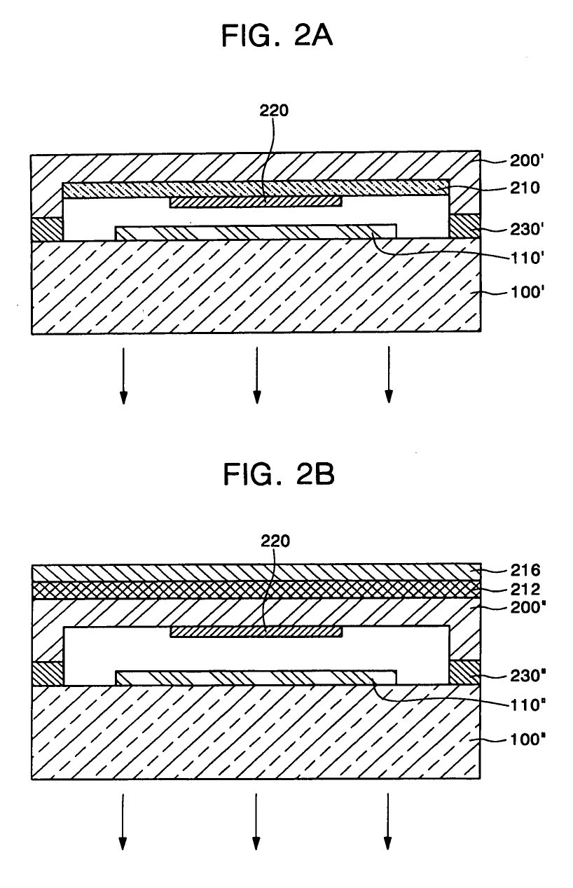

FIG. 2A is a cross-sectional view of a bottom-emitting OLED display having a reflective layer disposed on the surface of the second substrate according to another exemplary embodiment of the present invention.

Referring to FIG. 2A, a first substrate 100′ on which an OLED display element array 110′ is disposed may be adhered to a second substrate 200′ by an adhesive 230. The OLED display element array 110 may be made up of one or more OLED display elements. The OLED display element includes a pixel electrode, an organic layer having at least an emission layer, and an opposite electrode. The OLED display element also includes a thin-film transistor. The pixel electrode is a transparent electrode, while the opposite electrode is a reflective electrode. On a first surface of the second substrate 200′ of the OLED display, a reflective layer 210 may be disposed. The moisture absorbent material 220 may be disposed on the reflective layer 210. The reflective layer 210 may be disposed on the surface of the second substrate 200 corresponding to an emission region of the OLED display. In the former case, the moisture absorbent material 220 may be disposed on the reflective layer 210. In the latter case, the moisture absorbent material 220 may be disposed on the other surface of the second substrate 200 in which the reflective layer 210 is not disposed.

Referring to FIG. 2B, a reflective layer 212 may be disposed on a second surface of a second substrate 200″. In this case, since the reflective layer 212 is exposed, an optional passivation layer 216′, such as a transparent plastic layer, may be further disposed on the reflective layer 212. A first substrate 100″ on which an OLED display element array 110″ is disposed may be adhered to the second substrate 200″ by an adhesive 230″. The OLED display element array 110 may be made up of one or more OLED display elements. The OLED display element includes a pixel electrode, an organic layer having at least an emission layer, and an opposite electrode. The OLED display element also includes a thin-film transistor. The pixel electrode is a transparent electrode, while the opposite electrode is a reflective electrode. On a first surface of the second substrate 200″, a moisture absorbent material 220′ may be disposed. The reflective layer 212 may be formed of a material having a reflectivity of approximately 70% or more. The reflective layer 212 may be formed of at least one material selected from the group including Cr-based, Al-based, Ag-based, Sn-based, Mo-based, Fe-based, Pt-based, and Hg-based metals, and may be formed to a thickness of about 100 Å or more. The arrows below the bottom-emitting OLED display illustrate the direction of OLED emission (and corresponding OLED display) out of the OLED display to the device owner.

Hereinafter, a method of fabricating an OLED display according to an exemplary embodiment the present invention will be described with reference to FIG. 1.

A reflective layer 214 may be formed on one surface of a first substrate 100 by coating a metal having a reflectivity of approximately 70% or more on the entire surface thereof. The reflective layer 214 may be formed of at least one material selected from the group including Cr-based, Al-based, Ag-based, Sn-based, Mo-based, Fe-based, Pt-based, and Hg-based metals. Also, the reflective layer 214 may be formed to a thickness of about 100 Å or more. Although the reflective layer 214 may be formed after a subsequent process, alternately, it may be formed in advance to prevent deterioration of the OLED. Because the reflective layer 214 may be exposed, a transparent passivation layer 216 may be formed on the reflective layer 214.

On the other surface of the first substrate 100, a buffer layer (not shown) formed of silicon oxide may be deposited to a predetermined thickness using a plasma-enhanced chemical vapor deposition (PECVD) method. The buffer layer may prevent diffusion of impurities in the first substrate 100 during crystallization of an amorphous Si (a-Si) layer that may be formed in a subsequent process.

An a-Si layer having a predetermined thickness may be deposited on the buffer layer, crystallized by any number of methods including, but not limited to, an excimer laser annealing (ELA) method, a sequential lateral solidification (SLS) method, a metal induced crystallization (MIC) method, or a metal induced lateral crystallization (MILC) method, and then patterned by photolithography and etching processes, thereby forming a poly crystalline Si (poly-Si) pattern (not shown) in a thin-film transistor (TFT) region of a unit pixel. The poly-Si pattern may include source and drain regions (not shown), which may be formed in a subsequent process.

A gate insulating layer (not shown) having a predetermined thickness may be formed on the entire surface of the resultant structure. The gate insulating layer may be formed of silicon oxide, silicon nitride, or a laminated structure thereof.

A metal layer (not shown) for a gate electrode material may be formed on the gate insulating layer. The metal layer may be formed of a single layer of Al or an Al alloy (e.g., Al—Nd) or multiple layers including an Al alloy laminated on a Cr or Mo alloy. The metal layer may be etched by photolithography and etching processes, thereby forming a gate electrode (not shown). Impurities may be implanted into the poly-Si pattern below both sides of the gate electrode to form the source and drain regions.

An interlayer insulating layer (not shown) having a predetermined thickness may be formed on the entire surface of the resultant structure. The interlayer insulating layer may be formed of silicon nitride.

The interlayer insulating layer and the gate insulating layer may be etched using photolithography and etching processes, thereby forming a contact hole (not shown) to expose the source and drain regions. An electrode material may be formed on the entire surface of the resultant structure including the contact hole and etched using photolithography and etching processes. Thus, source and drain electrodes (not shown), which are in contact with the source and drain regions respectively, are formed. The electrode material may be MoW or Al—Nd.

On the entire surface of the resultant structure, a passivation layer 216 having a predetermined thickness may be formed of a silicon nitride layer, a silicon oxide layer, or a laminated structure thereof.

Subsequently, the passivation layer 216 may be etched using photolithography and etching processes, thereby forming a first via contact hole (not shown) to expose either the source electrode or the drain electrode.

A first insulating layer (not shown) may be formed on the entire surface of the resultant structure. The first insulating layer may be formed to such a thickness as to completely planarize the TFT region and formed of one material selected from the group including polyimide, benzocyclobutene series resin, spin on glass (SOG), and acrylate.

The first insulating layer may be etched using photolithography and etching processes, thereby forming a second via contact hole (not shown) to expose either the source electrode or the drain electrode through the first via contact hole.

A thin layer (not shown) for a pixel electrode may be formed on the entire surface of the resultant structure. The thin layer for the pixel electrode may be formed of a laminated structure of a metal layer having a high reflectivity, and a transparent metal layer, such as an indium tin oxide (ITO) layer.

The thin layer for the pixel electrode may be etched using photolithography and an etching process to form a pixel electrode. The pixel electrode may be connected to either the source electrode or the drain electrode through the second via contact hole.

A second insulating layer (not shown) may be formed on the entire surface of the resultant structure. The second insulating layer may be etched using photolithography and etching processes, thereby forming a second insulating layer pattern to define an emission region.

An organic layer may be formed in a portion of the emission region, which may be exposed by the second insulating layer pattern. The organic layer may be formed by any number of methods including, but not limited to, a small molecule deposition method, a laser induced thermal imaging method, or an inkjet method. The organic layer may include an emission layer and may further include at least one material selected from the group including an electron injection layer, an electron transport layer, a hole injection layer, a hole transport layer, a hole blocking layer or an organic emission layer.

A portion of an opposite electrode may be formed on the organic layer. A second substrate 200 may be prepared and adhered to the first substrate 100 using an adhesive 230 aligned with the first substrate 100.

Although an exemplary embodiment of a method of fabricating a top-emitting OLED was described with reference to FIG. 1, a bottom-emitting OLED may be fabricated in a similar manner (with reference to FIGS. 2A and 2B) except for the position of the reflective layer 210, and the transparency or reflectivity of the pixel electrode and the opposite electrode.

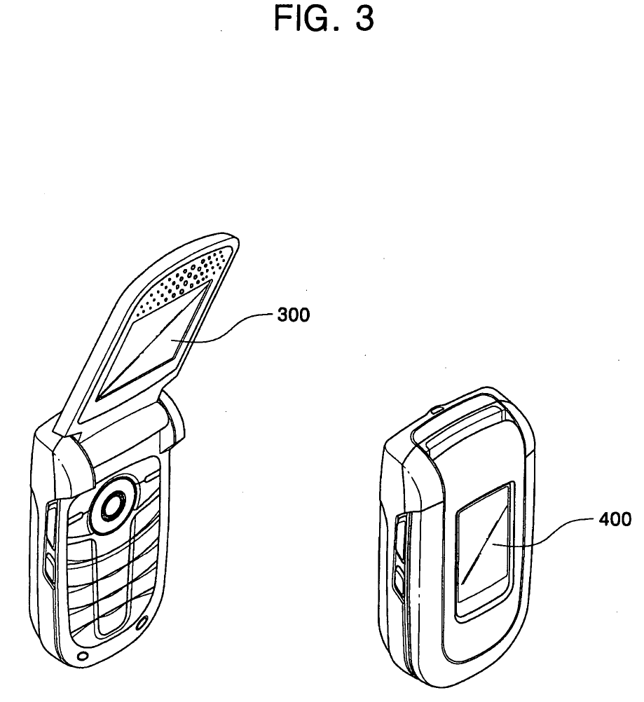

FIG. 3 illustrates a mobile phone using an OLED display fabricated according to the present invention. Referring to FIG. 3, the mobile phone includes an internal window 300 as a display and an external window 400 as a mirror. Thus, whenever in need of a mirror, like when meeting someone outdoors or after having a meal, a user can adjust himself or herself by using the external window 400 of the mobile phone as a mirror.

Exemplary embodiments of methods of fabricating an OLED display according to the present invention have been described in the general context of method steps. However, as will be understood by those skilled in the art, the foregoing methods are not limited to the exemplary sequence of steps and a variety of modifications and variations to the exemplary methods may be made without departing from the spirit or scope of the present invention defined in the appended claims, and their equivalents.

Further, although structures of the present invention have been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. An organic light emitting diode display comprising:
a first substrate having a first surface on which at least one organic light emitting diode display element is disposed, the at least one organic light emitting diode display element comprising: a pixel electrode; an organic layer having at least an emission layer; a portion of an opposite electrode; and at least one thin-film transistor positioned between the first substrate and the pixel electrode;
a second substrate encapsulating the at least one organic light emitting display element; and
a reflective layer on a surface of one of the first substrate and the second substrate.

2. The display according to claim 1, wherein the reflective layer is a metal layer having a reflectivity of approximately 70% or more.

3. The display according to claim 1, wherein the reflective layer is formed of at least one material selected from the group consisting of Cr-based, Al-based, Ag-based, Sn-based, Mo-based, Fe-based, Pt-based, and Hg-based metals.

4. The display according to claim 1, wherein the reflective layer has a thickness of about 100 Å or more.

5. The display according to claim 1, further comprising a passivation layer disposed on the reflective layer.

6. An organic light emitting diode display comprising:
a first substrate comprising:
a first surface on which at least one organic light emitting diode display element is disposed, the at least one organic light emitting diode display element comprising: a pixel electrode; an organic layer having at least an emission layer; a portion of an opposite electrode; and at least one thin-film transistor positioned between the first substrate and the pixel electrode; and
a second surface on which a reflective layer is disposed; and
a second substrate for encapsulating the at least one organic light emitting diode display element.

7. The display according to claim 6, wherein the pixel electrode is a reflective electrode, and the opposite electrode is a transparent electrode.

8. The display according to claim 6, wherein the reflective layer is a metal layer having a reflectivity of approximately 70% or more.

9. The display according to claim 6, wherein the reflective layer is formed of at least one material selected from the group consisting of Cr-based, Al-based, Ag-based, Sn-based, Mo-based, Fe-based, Pt-based, and Hg-based metals.

10. The display according to claim 6, wherein the reflective layer has a thickness of about 100 Å or more.

11. The display according to claim 6, further comprising a passivation layer disposed on the reflective layer.

12. An organic light emitting diode display comprising:
a first substrate on which at least one organic light emitting diode display element is disposed, the at least one organic light emitting diode display element comprising: a pixel electrode; an organic layer having at least an emission layer; a portion of an opposite electrode; and at least one thin-film transistor positioned between the first substrate and the pixel electrode;
a second substrate for encapsulating the at least one organic light emitting diode display element; and
a reflective layer disposed on a surface of the second substrate.

13. The display according to claim 12, wherein the pixel electrode is a transparent electrode, and the opposite electrode is a reflective electrode.

14. The display according to claim 12, wherein the reflective layer is a metal layer having a reflectivity of approximately 70% or more.

15. The display according to claim 12, wherein the reflective layer is formed of at least one material selected from the group consisting of Cr-based, Al-based, Ag-based, Sn-based, Mo-based, Fe-based, Pt-based, and Hg-based metals.

16. The display according to claim 12, wherein the reflective layer has a thickness of about 100 Å or more.

17. The display according to claim 12, wherein the reflective layer is disposed on a first, inner surface of the second substrate.

18. The display according to claim 12, wherein the reflective layer is disposed on a second, outer surface of the second substrate.

19. The display according to claim 18, further comprising a passivation layer disposed on the reflective layer.

20. The display according to claim 18, further comprising a moisture absorbent material disposed on the first surface of the second substrate.

21. The display according to claim 17, further comprising a moisture absorbent material disposed on a first surface of the reflective layer.
